(19) United States
(12) Patent Application Publication
(10) Pub. No.: US 2016/0241242 A1
(43) Pub. Date: Aug. 18, 2016

(54) DRIVE UNIT

(71) Applicant: TOYOTA JIDOSHA KABUSHIKI KAISHA, Toyota-shi (JP)

(72) Inventor: Ken TOSHIYUKI, Seto-shi (JP)

(73) Assignee: TOYOTA JIDOSHA KABUSHIKI KAISHA, Toyota-shi (JP)

(21) Appl. No.: 15/017,002

(22) Filed: Feb. 5, 2016

(30) Foreign Application Priority Data
Feb. 13, 2015 (JP) 2015-026858

(51) Int. Cl. H03K 19/018

(52) U.S. Cl. CPC H03K 19/01806

(57) ABSTRACT

A drive unit includes a reverse conducting transistor including a transistor and a first diode being connected in inverse-parallel to the transistor, the transistor and the first diode being provided on a common semiconductor substrate; a second diode including a cathode being connected to a collector of the transistor the second diode being provided on the semiconductor substrate; and a detection portion configured to detect a voltage between the collector and an emitter of the transistor via an anode of the second diode.

### INCORPORATION BY REFERENCE

The disclosure of Japanese Patent Application No. 2015-026858 filed on Feb. 13, 2015 including the specification, drawings and abstract is incorporated herein by reference in its entirety.

### BACKGROUND OF THE INVENTION

1. Field of the Invention

The invention relates to a drive unit.

2. Description of Related Art

A drive unit is known that includes a reverse conducting transistor that has a transistor and a first diode that is connected in inverse-parallel to the transistor, the transistor and the first diode being provided on a common semiconductor substrate, and a second diode that has a cathode that is connected to a collector of the transistor (refer to Japanese Patent Application Publication No. 2014-216932 (JP 2014-216932 A), for example). This drive unit has a configuration in which a voltage V_{CE} between the collector and emitter of the transistor is detected via an anode of the second diode.

However, a forward voltage of the first diode and a forward voltage of the second diode respectively have the characteristic of changing with temperature (temperature characteristic). Thus, when the temperature of the first diode and the temperature of the second diode vary independently of each other, the forward voltage of the first diode and the forward voltage of the second diode also change independently of each other and the detection value of the voltage V_{CE} therefore varies widely.

### SUMMARY OF THE INVENTION

It is, therefore, an object of the invention is to provide a drive unit in which the detection value of the voltage between a collector and an emitter does not vary widely.

A drive unit according to an aspect of the invention includes: a reverse conducting transistor including a transistor and a first diode being connected in inverse-parallel to the transistor, the transistor and the first diode being provided on a first semiconductor substrate; a second diode including a cathode being connected to a collector of the transistor, the second diode being provided on the first semiconductor substrate; and a detection portion configured to detect a voltage between the collector and an emitter of the transistor via an anode of the second diode.

According to the above aspect, because the first diode and the second diode are provided on a first semiconductor substrate, the difference between the temperature of the first diode and the temperature of the second diode decreases and these temperatures vary in an approximately similar fashion. Thus, even when each of the forward voltages of the first and second diodes changes with variation in temperature, the variation in the detection value of the voltage between the collector and emitter of the transistor decreases as compared to a case where the temperatures of the first and second diodes vary independently of each other.

### BRIEF DESCRIPTION OF THE DRAWINGS

Features, advantages, and technical and industrial significance of exemplary embodiments of the invention will be described below with reference to the accompanying drawings, in which like numerals denote like elements, and wherein:

FIG. 1 is a diagram that illustrates one example of the configuration of a drive unit;

FIG. 2 is a diagram that illustrates another example of the configuration of a drive unit;

FIG. 3 is a diagram that illustrates another example of the configuration of a drive unit;

FIG. 4 is a diagram that illustrates one example of an arrangement position of a second diode; and

FIG. 5 is a diagram that illustrates one example of the configuration of a power converter that is equipped with a plurality of drive units.

### DETAILED DESCRIPTION OF EMBODIMENTS

Embodiments of the invention are hereinafter described with reference to the drawings.

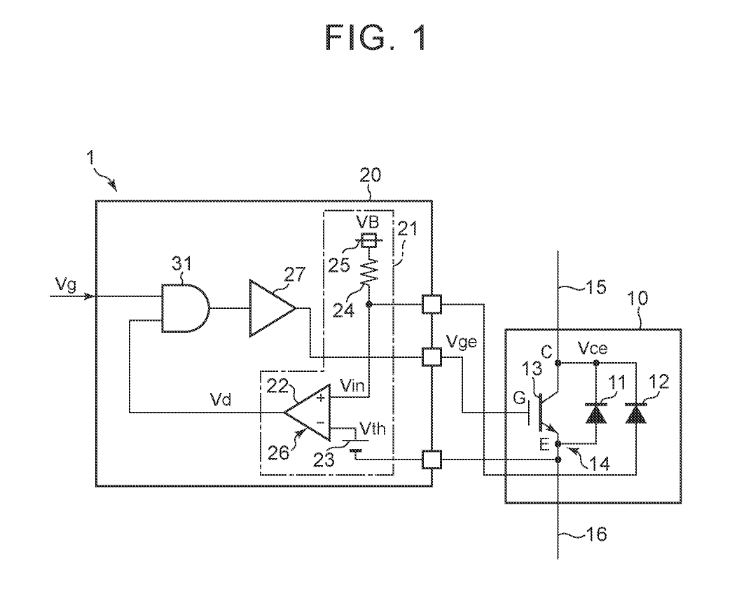

FIG. 1 is a diagram that illustrates one example of the configuration of a drive unit 1 according to a first embodiment. The drive unit 1 is a semiconductor device that drives an inductive load (such as an inductor, motor or the like) that is connected to a first current path 15 or a second current path 16 by on-off driving of a reverse conducting transistor 14, for example.

The first current path 15 is an electric wiring that is conductively connected to a source voltage VH of a high source potential part, such as a positive electrode of a power source, for example. The first current path 15 may be indirectly connected to the source voltage VH of the high source potential part via another switching element or load. The second current path 16 is an electric wiring that is conductively connected to a low source potential part, such as a negative electrode of a power source (for example, ground), for example. The second current path 16 may be indirectly connected to the low source potential part via another switching element or load.

One example of a device in which one or more drive units 1 are used is a power converter that converts electric power between input and output by on-off driving of the reverse conducting transistor 14, for example. Specific examples of the power converter include a converter that increase or decrease the voltage of DC power, and an inverter that performs power conversion between DC power and AC power.

The drive unit 1 includes a semiconductor substrate 10, and a drive circuit board 20 that is separate from the semiconductor substrate 10. The semiconductor substrate 10 is a chip that has the reverse conducting transistor 14, and a protection diode 12, for example. The drive circuit board 20 is an integrated circuit (IC) that has a detection part 21, a determination part 31, and a drive part 27, for example.

The reverse conducting transistor 14 is one example of a reverse conducting transistor that has a transistor 13 and a flyback diode 11 that are provided together on the common semiconductor substrate 10. The transistor 13 has a gate G, a collector C, and an emitter E. The flyback diode 11 has an electrode that uses the emitter E of the transistor 13 as an anode, and an electrode that uses the collector C of the transistor 13 as a cathode. In other words, the reverse conducting transistor 14 is a switching element that has a structure in which a common electrode that serves as the emitter E of the transistor 13 and as the anode of the flyback diode 11 and a common electrode that serves as the collector C of the transistor 13 and the cathode of the flyback diode 11 are formed. The flyback diode 11 is one example of a first diode that is connected in inverse-parallel to the transistor 13.

The reverse conducting transistor 14 is a reverse conducting insulated gate bipolar transistor (RC-IGBT) that uses the transistor 13 as an insulated gate bipolar transistor (IGBT), for example. An RC-IGBT is sometimes referred to as built-in diode IGBT.

The protection diode 12 is one example of a second diode that is provided on the common semiconductor substrate 10 on which the reverse conducting transistor 14 is provided. The protection diode 12 has a cathode that is connected to the collector C of the transistor 13, and an anode that is connected to the detection part 21 of the drive circuit board 20. The protection diode 12 can protect the drive circuit board 20 (in particular, the detection part 21) from a voltage Vce with an increased voltage value. The voltage Vce is the voltage between the collector C and the emitter E of the transistor 13.

The detection part 21 is one example of a detection part that detects whether the flyback diode 11 is electrified by detecting the voltage Vce via the anode of the protection diode 12. The detection part 21 has a voltage source 25, a resistance 24, and a monitor circuit 26, for example.

The anode of the protection diode 12 is in pull-up connection with a voltage VB of the voltage source 25 via the resistance 24. The resistance 24 may be a constant current source that outputs a constant current. The voltage source 25 shares a ground with the drive circuit board 20. The ground of the drive circuit board 20 is conductively connected to the emitter E of the transistor 13. The connecting point between the anode of the protection diode 12 and the resistance 24 is connected to the monitor circuit 26, and an input voltage Vin is input into the monitor circuit 26 via the connecting point. In other words, the input voltage Vin corresponds to one example of a detection value of the voltage Vce. The detection part 21 detects whether the flyback diode 11 is electrified based on the voltage value of the input voltage Vin that is input into the monitor circuit 26.

For example, when the flyback diode 11 is electrified, a forward current flows through the flyback diode 11 and the voltage Vce is therefore equal to −VF11 (the emitter E of the transistor 13 is defined to have a reference potential of zero and VF11 is defined to be a forward voltage of the flyback diode 11). Because the voltage Vce (=−VF11) at this time is lower than the voltage VB, the protection diode 12 is electrified in a forward direction. Thus, when the flyback diode 11 is electrified, the input voltage Vin is equal to “−VF11+VF12,” which is higher than the voltage Vce by the amount of the forward voltage VF12 of the protection diode 12.

When the flyback diode 11 is not electrified, the voltage Vce is equal to an on-voltage Von of the transistor 13 if the transistor 13 is electrified. The on-voltage Von is the voltage that is developed between the collector C and the emitter E when the transistor 13 is electrified. Because the voltage Vce (=Von) at this time is also lower than the voltage VB, the protection diode 12 is electrified in a forward direction. Thus, when the flyback diode 11 is not electrified and the transistor 13 is electrified, the input voltage Vin is equal to “Von+VF12,” which is higher than the voltage Vce by the amount of the forward voltage VF12 of the protection diode 12.

When neither the flyback diode 11 nor the transistor 13 are electrified, the voltage Vce is approximately equal to the source voltage VH of the high source potential part that is directly or indirectly connected to the first current path 15. Because the voltage Vce (=VH) at this time is higher than the voltage VB, the protection diode 12 is not electrified. Thus, when neither the flyback diode 11 nor the transistor 13 is electrified, the input voltage Vin is equal to the “voltage VB.” It should be noted that the voltage VB is set to a voltage value that is higher than “Von+VF12” and lower than the source voltage VH.

As described above, the voltage value of the input voltage Vin that is input into the monitor circuit 26 of the detection part 21 changes depending on whether the flyback diode 11 is electrified. Thus, the detection part 21 can detect whether the flyback diode 11 is electrified by detecting the difference in the voltage value of the input voltage Vin that is input into the monitor circuit 26.

However, the forward voltage VF11 of the flyback diode 11 and the forward voltage VF12 of the protection diode 12 both have the characteristic of changing with temperature (temperature characteristic). Thus, when the temperature of the flyback diode 11 and the temperature of the protection diode 12 vary independently of each other, the forward voltage VF11 and the forward voltage VF12 change independently of each other and the voltage value of the input voltage Vin therefore varies widely. As a result, the accuracy of the detection of whether the flyback diode 11 is electrified by the monitor circuit 26 of the detection part 21 is lowered.

For example, because the process cost of the drive circuit board 20 is lower than the process cost of the semiconductor substrate 10 on which the reverse conducting transistor 14 is provided, a case is assumed where the protection diode 12 that can protect the detection part 21 is provided, together with the detection part 21, on the drive circuit board 20. However, because the reverse conducting transistor 14 as a heat source is provided on the semiconductor substrate 10, the temperatures of the flyback diode 11 and the protection diode 12 vary independently of each other when the flyback diode 11 and the protection diode 12 are provided on different substrates. As a result, the voltage value of the input voltage Vin varies widely, and, consequently, the accuracy of the detection of whether the flyback diode 11 is electrified is lowered.

In contrast to this, in this embodiment, the temperature of the flyback diode 11 and the temperature of the protection diode 12 do not vary independently of each other but vary in an approximately similar fashion because the protection diode 12 is provided on the common semiconductor substrate 10 on which the flyback diode 11 is provided. Thus, even when the forward voltage VF11 and the forward voltage VF12 independently change with variation in temperature, the variation of the voltage value of the input voltage Vin decreases as compared to a case where the temperatures of the flyback diode 11 and the protection diode 12 vary independently of each other. As a result, the accuracy of the detection of whether the flyback diode 11 is electrified by the monitor circuit 26 of the detection part 21 can be improved.

In addition, because the cathode of the protection diode 12 is connected to the collector of the transistor 13 to which the flyback diode 11 is connected in inverse-parallel, the forward direction of the flyback diode 11 and the forward direction of the protection diode 12 are opposite to each other. In other words, the cathode of the flyback diode 11 and the cathode of the protection diode 12 are connected to each other. Therefore, because the variation of the forward voltage VF11 with temperature and the variation of the forward voltage VF12 with temperature are cancelled out almost completely, the variation in the voltage value of the input voltage Vin decreases. As a result, the accuracy of the detection of whether the flyback diode 11 is electrified by the monitor circuit 26 of the detection part 21 can be improved.

The flyback diode 11 and the protection diode 12 may be different kinds of diodes but are preferably diodes of the same kind. When both the diodes are of the same kind, the temperature characteristics of the forward voltages of both the diodes can be the same. In this case, because the variation of the forward voltage VF11 with temperature and the variation of the forward voltage VF12 with temperature can be equalized, the variation in the voltage value of the input voltage Vin further decreases. As a result, the accuracy of the detection of whether the flyback diode 11 is electrified by the monitor circuit 26 of the detection part 21 can be further improved.

The detection part 21 outputs a detection signal Vd that indicates the result of the detection of whether the flyback diode 11 is electrified from the monitor circuit 26 based on the voltage value of the input voltage Vin. For example, the monitor circuit 26 has a comparator 22, and a threshold voltage generation part 23 in order to output a detection signal Vd that indicates the result of the detection of whether the flyback diode 11 is electrified.

The comparator 22 has a non-inverting input that is connected to the connecting point between the anode of the protection diode 12 and the resistance 24, and an inverting input that is connected to the threshold voltage generation part 23. The threshold voltage generation part 23 generates a threshold voltage Vth using the ground of the drive circuit board 20 as a ground reference, and provides the threshold voltage Vth to the inverting input of the comparator 22. The comparator 22 compares the magnitude relationship between the input voltage Vin and the threshold voltage Vth to detect whether the flyback diode 11 is electrified.

The threshold voltage Vth is set to a voltage value that is higher than “−VF11+VF12” and lower than “Von+VF12.” Thus, the comparator 22 outputs a low-level detection signal Vd that indicates that the flyback diode 11 is electrified when it detects that the input voltage Vin is lower than the threshold voltage Vth. On the other hand, the comparator 22 outputs a high-level detection signal Vd that indicates that the flyback diode 11 is not electrified when it detects that the input voltage Vin is higher than the threshold voltage Vth.

For example, when “VF11=VF12=Von=1[V],” the threshold voltage Vth is set to a voltage value that is higher than 0[V] and lower than 2[V] because “−VF11+VF12=0[V]” and “Von+VF12=2[V]”. In this case, the detection part 21 can detect electrification of the flyback diode 11 even when a minute current which is slightly higher than 0 ampere flows through the flyback diode 11.

The determination part 31 determines whether to permit the transistor 13 to be turned on based on the result of the detection of whether the flyback diode 11 is electrified by the detection part 21. When the detection part 21 detects that the flyback diode 11 is electrified (for example, when a low-level detection signal Vd is input into the determination part 31), the determination part 31 prohibits the transistor 13 from being turned on. On the other hand, when the detection part 21 detects that the flyback diode 11 is not electrified (for example, when a high-level detection signal Vd is input into the determination part 31), the determination part 31 permits the transistor 13 to be turned on.

The determination part 31 has an AND circuit (AND gate) into which a command signal Vg and the detection signal Vd are input, for example. The command signal Vg is a pulse width modulation (PWM) signal that is provided from a controller outside of the drive circuit board 20, for example. A high-level command signal Vg represents an on-command for the transistor 13, and a low-level command signal Vg represents an off-command for the transistor 13. The controller that outputs the command signal Vg is a microcomputer that includes a central processing unit (CPU), for example. It should be noted that the controller that outputs the command signal Vg may be provided on the drive circuit board 20.

When the transistor 13 is prohibited from being turned on by the determination part 31, the drive part 27 maintains a gate voltage Vge of the transistor 13 at a voltage value at which the transistor 13 is fixed in an off state even if a command signal Vg that commands turn-on of the transistor 13 is input. On the other hand, the drive part 27 turns on or off the transistor 13 according to the command signal Vg when the transistor 13 is permitted to be turned on by the determination part 31. In other words, the drive part 27 changes the gate voltage Vge to a voltage value at which the transistor 13 is turned on when the command signal Vg is an on-command for the transistor 13 and changes the gate voltage Vge to a voltage value at which the transistor 13 is turned off when the command signal Vg is an off-command for the transistor 13.

In the reverse conducting transistor 14, when the transistor 13 is turned on while a current is flowing through the flyback diode 11, the forward voltage VF11 increases and the forward loss of the flyback diode 11 increases. This phenomenon is sometimes referred to as “gate interference.” However, when the transistor 13 is prohibited from being turned on by the determination part 31, the transistor 13 is maintained in an off state even if a command signal Vg that commands turn-on of the transistor 13 is input. Thus, an increase in forward loss of the flyback diode 11 can be prevented. This can lead to a reduction of power consumption of the drive unit 1 and, consequently, contribute to improvement of the fuel efficiency of the vehicle that is equipped with the drive unit 1, for example.

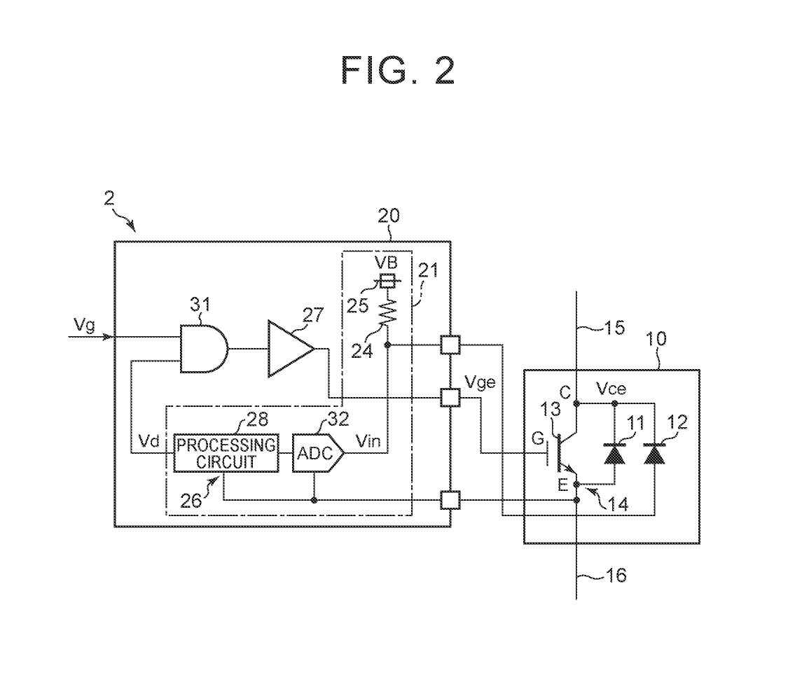

FIG. 2 is a diagram that illustrates one example of the configuration of a drive unit 2 according to a second embodiment. As for the same configurations and effects as those of the above-mentioned drive unit 1, the description of the drive unit 1 is incorporated. The drive unit 2 has a monitor circuit 26 that is different in configuration from that of the drive unit 1. The monitor circuit 26 of the drive unit 2 has an ADC 32 and a processing circuit 28 in order to output a detection signal Vd that indicates the result of the detection of whether the flyback diode 11 is electrified.

The ADC 32 is an AD (Analog-to-Digital) converter that has an input that is connected to the connecting point between the anode of the protection diode 12 and the resistance 24. The ADC 32 converts an analog value of the input voltage Vin into a digital value and outputs the digital value to the processing circuit 28. The processing circuit 28 compares the magnitude relationship between the digital value of the input voltage Vin and a digital value of the threshold voltage Vth, and outputs a detection signal Vd that indicates the result of the detection of whether the flyback diode 11 is electrified.

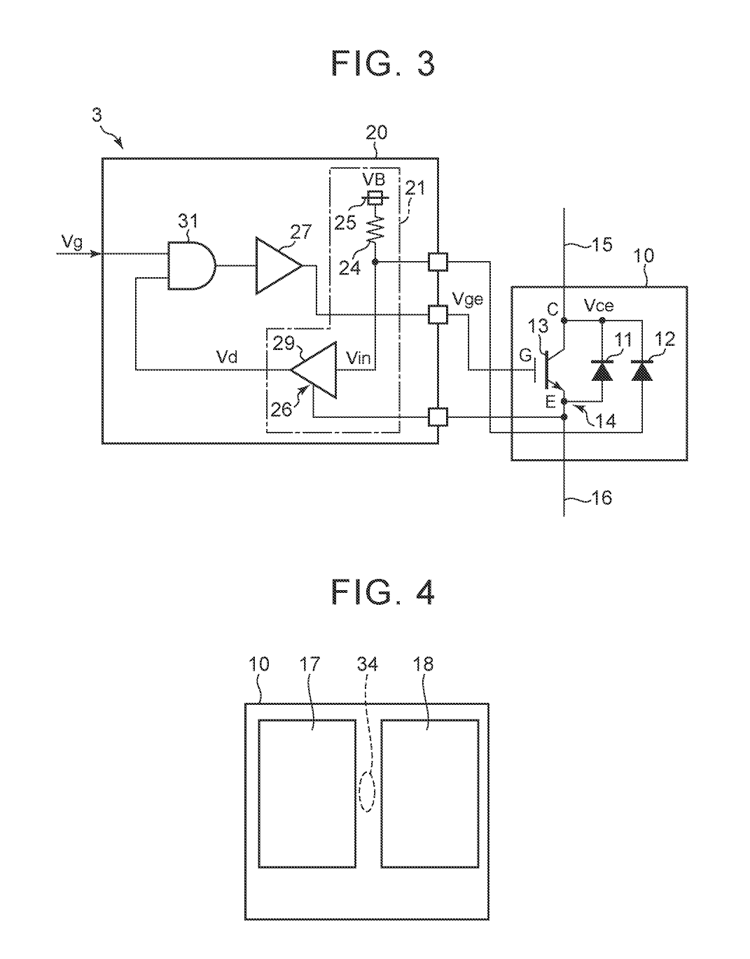

FIG. 3 is a diagram that illustrates one example of the configuration of a drive unit 3 according to a third embodiment. As for the same configurations and effects as those of the above-mentioned drive unit 1, the description of the drive unit 1 is incorporated. The drive unit 3 has a monitor circuit 26 that is different in configuration from that of the drive unit 1. The monitor circuit 26 of the drive unit 3 has a buffer circuit 29 in order to output a detection signal Vd that indicates the result of the detection of whether the flyback diode 11 is electrified.

The buffer circuit 29 has an input that is connected to the connecting point between the anode of the protection diode 12 and the resistance 24. A threshold value of the input of the buffer circuit 29 is set to the threshold voltage Vth. The buffer circuit 29 compares the magnitude relationship between the input voltage Vin and the threshold voltage Vth, and outputs a detection signal Vd that indicates the result of the detection of whether the flyback diode 11 is electrified.

FIG. 4 is a diagram that illustrates one example of an arrangement position of the protection diode 12. FIG. 4 is a plan view that schematically illustrates the semiconductor substrate 10. The semiconductor substrate 10 has element active regions 17 and 18 in which the reverse conducting transistor 14 is located. In the illustrated case, the protection diode 12 is located at a central part 34 of the rectangular-shaped semiconductor substrate 10 (specifically, in a region between the first element active region 17 and the second element active region 18). The difference in temperature between the central part 34 and the element active regions 17 and 18 is relatively small.

Thus, because the difference in temperature between the flyback diode 11 and the protection diode 12 is small as the protection diode 12 is located at the central part 34, the temperatures of both the diodes do not vary independently of each other but vary in an approximately similar fashion. Thus, because the variation in the voltage value of the input voltage Vin decreases, the accuracy of the detection of whether the flyback diode 11 is electrified by the monitor circuit 26 of the detection part 21 can be further improved.

It should be noted that the protection diode 12 does not necessarily have to be located at the central part 34 of the semiconductor substrate 10 and may be located in a region other than the central part 34 (for example, in a region between an element active region and an edge of the semiconductor substrate 10).

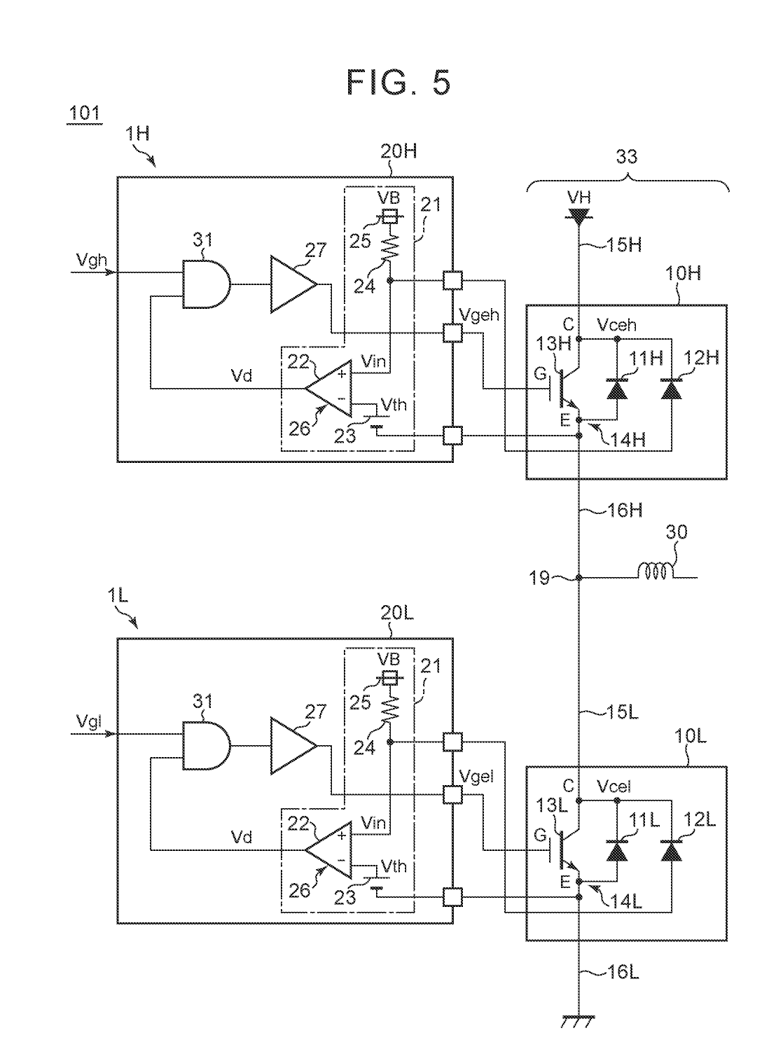

FIG. 5 is a diagram that illustrates one example of the configuration of a power converter 101 that is equipped with a plurality of drive units. As for the same configurations and effects as those of the above-mentioned drive unit 1, the description of the drive unit 1 is incorporated. The power converter 101 includes a pair of drive units 1L and 1H, each of which has the same configuration as the drive unit 1. The power converter 101 includes the drive unit 1L that is provided on a low side with respect to an intermediate node 19, and the drive unit 1H that is provided on a high side with respect to the intermediate node 19. An inductive load 30 is connected to the intermediate node 19.

A current path 15L is connected to a high source potential part of a source voltage VH via a reverse conducting transistor 14H, and a current path 16L is connected to a ground. A current path 15H is connected to the high source potential part of the source voltage VH, and a current path 16H is connected to the ground via a reverse conducting transistor 14L.

The power converter 101 includes an arm circuit 33 in which the reverse conducting transistor 14L of the drive unit 1L and the reverse conducting transistor 14H of the drive unit 1H are connected in series. When used as an inverter that drives a three-phase motor, the power converter 101 includes three arm circuits 33, i.e., as many arm circuits 33 as the number of phases of the three-phase motor, that are provided in parallel.

The drive unit 1L includes a semiconductor substrate 10L, and a drive circuit board 20L. The semiconductor substrate 10L is a chip that has the reverse conducting transistor 14L, and a protection diode 12L. A voltage Vcel is the voltage between a collector C and an emitter E of a transistor 13L. On the other hand, the drive unit 1H includes a semiconductor substrate 10H, and a drive circuit board 20H. The semiconductor substrate 10H is a chip that has the reverse conducting transistor 14H, and a protection diode 12H. A voltage Vceh is the voltage between a collector C and an emitter E of a transistor 13H.

While a high level command signal Vgl that commands turn-on of the transistor 13L is being input into the drive unit 1L, a low level command signal Vgh that commands turn-off of the transistor 13H is being input into the drive unit 1H. On the other hand, while a high level command signal Vgh that commands turn-on of the transistor 13H is being input into the drive unit 1H, a low level command signal Vgl that commands turn-off of the transistor 13L is being input into the drive unit 1L.

When the transistor 13L is prohibited from being turned on by the determination part 31 of the drive unit 1L, the drive part 27 of the drive unit 1L maintains a gate voltage Vgel of the transistor 13L at a voltage value at which the transistor 13L is fixed in an off state even if a command signal Vgl that commands turn-on of the transistor 13L is input. On the other hand, the drive part 27 of the drive unit 1L turns on or off the transistor 13L according to the command signal Vgl when the transistor 13L is permitted to be turned on by the determination part 31 of the drive unit 1L.

When the transistor 13H is prohibited from being turned on by the determination part 31 of the drive unit 1H, the drive part 27 of the drive unit 1H maintains a gate voltage Vgeh of the transistor 13H at a voltage value at which the transistor 13H is fixed in an off state even if a command signal Vgh that commands turn-on of the transistor 13H is input. On the other hand, the drive part 27 of the drive unit 1H turns on or off the transistor 13H according to the command signal Vgh when the transistor 13H is permitted to be turned on by the determination part 31 of the drive unit 1H.

When a flyback diode 11L is electrified, the voltage Vcel is equal to −VF11 due to the electrification of the flyback diode 11L. Because the voltage Vcel is lower than the voltage VB, the protection diode 12L is electrified. Thus, when the flyback diode 11L is electrified, the input voltage Vin is equal to “−VF11+VF12.”

On the other hand, when the flyback diode 11L is not electrified, the voltage Vcel is equal to the on voltage Von of the transistor 13L if the transistor 13L is electrified. Because the voltage Vcel is lower than the voltage VB, the protection diode 12L is electrified. Thus, when the flyback diode 11L is not electrified and the transistor 13L is electrified, the input voltage Vin is equal to “Von+VF12.”

Further, when neither the flyback diode 11L nor the transistor 13L are electrified, the voltage Vcel is approximately equal to the source voltage VH due to turn-on of the transistor 13H or electrification of the flyback diode 1114. Because the voltage Vcel is higher than the voltage VB, the protection diode 12L is not electrified. Thus, when neither the flyback diode 11L nor the transistor 13L is electrified, the input voltage Vin is equal to the “voltage VB.”

Thus, the detection part 21 of the drive unit 1L can detect whether the flyback diode 11L is electrified by detecting the difference in the voltage value of the input voltage Vin that is input into the monitor circuit 26 of the drive unit 1L. In addition, because the protection diode 12L is provided on the common semiconductor substrate 10L on which the flyback diode 11L is provided, the variation in the voltage value of the input voltage Vin decreases. As a result, the accuracy of the detection of whether the flyback diode 11L is electrified by the monitor circuit 26 of the detection part 21 of the drive unit 1L can be improved.

Because the drive unit 1H also operates in the same manner as the drive unit 1L, the accuracy of the detection of whether the flyback diode 11H is electrified by the monitor circuit 26 of the detection part 21 of the drive unit 1H can be improved.

While the drive unit is described with reference to its embodiments in the foregoing, the invention is not limited to the above embodiments. Various modifications and improvements, such as a combination or replacement with a part or whole of another embodiment, can be made.

For example, the RC-IGBT is one example of the reverse conducting transistor, and the reverse conducting transistor may be a different kind of switching element.

In addition, the detection part that detects whether a diode that is connected in inverse-parallel to the transistor is electrified does not necessarily have to be provided on a substrate that is different from the semiconductor substrate on which the reverse conducting transistor is provided and may be provided on the semiconductor substrate on which the reverse conducting transistor is provided.

Alternatively, the detection part 21 may detect the electrification direction of the reverse conducting transistor 14 by detecting the voltage Vce via the anode of the protection diode 12. A current that flows through the reverse conducting transistor 14 in a positive direction from the collector to the emitter flows through the transistor 13, and a current that flows through the reverse conducting transistor 14 in a negative direction from the emitter to the collector flows through the flyback diode 11. Thus, when the direction of the current that flows through the reverse conducting transistor 14 is positive (in other words, when the transistor 13 is electrified), the input voltage Vin is equal to “Von+VF12.” On the other hand, when the direction of the current that flows through the reverse conducting transistor 14 is negative (in other words, when the flyback diode 11 is electrified), the input voltage Vin is equal to “−VF11+VF12.”

As described above, the voltage value of the input voltage Vin that is input into the monitor circuit 26 of the detection part 21 changes depending on the difference in the direction of the current that flows through the reverse conducting transistor 14. Thus, the detection part 21 can detect the electrification direction of the reverse conducting transistor 14 by detecting the difference in the voltage value of the input voltage Vin that is input into the monitor circuit 26.

For example, the comparator 22 outputs a low-level detection signal Vd that indicates that the electrification direction of the reverse conducting transistor 14 is negative (in other words, the flyback diode 11 is electrified) when it detects that the input voltage Vin is lower than a first threshold voltage Vth1. The first threshold voltage Vth1 is set to a voltage value that is higher than “−VF11+VF12” and lower than “Von+VF12.” On the other hand, the comparator 22 outputs a high-level detection signal Vd that indicates that the electrification direction of the reverse conducting transistor 14 is positive (in other words, the transistor 13 is electrified) when it detects that the input voltage Vin is higher than the first threshold voltage Vth1 and lower than a second threshold voltage Vth2. The second threshold voltage Vth2 is higher than the first threshold voltage Vth1. The second threshold voltage Vth2 is set to a voltage value that is higher than “Von+VF12” and lower than “VB.”

The determination part 31 determines whether to permit the transistor 13 to be turned on based on the result of the detection of the electrification direction of the reverse conducting transistor 14 by the detection part 21. When the detection part 21 detects that the electrification direction of the reverse conducting transistor 14 is negative (in other words, the flyback diode 11 is electrified) (for example, when a low-level detection signal Vd is input into the determination part 31), the determination part 31 prohibits the transistor 13 from being turned on. On the other hand, when the detection part 21 detects that the electrification direction of the reverse conducting transistor 14 is positive (in other words, the transistor 13 is electrified) (for example, when a high-level detection signal Vd is input into the determination part 31), the determination part 31 permits the transistor 13 to be turned on.

Alternatively, the detection part 21 may detect whether the transistor 13 is electrified by detecting the voltage Vce via the anode of the protection diode 12. When the transistor 13 is electrified, the input voltage Vin is equal to “Von+VF12.” On the other hand, when the transistor 13 is not electrified, the input voltage Vin is equal to “−VF11+VF12” or “voltage VB.”

As described above, the voltage value of the input voltage Vin that is input into the monitor circuit 26 of the detection part 21 changes depending on whether the transistor 13 is electrified. Thus, the detection part 21 can detect whether the transistor 13 is electrified by detecting the difference in the voltage value of the input voltage Vin that is input into the monitor circuit 26.

For example, the comparator 22 outputs a low-level detection signal Vd that indicates that the transistor 13 is not electrified when it detects that the input voltage Vin is lower than a first threshold voltage Vth1 or higher than a second threshold voltage Vth2. The second threshold voltage Vth2 is higher than the first threshold voltage Vth1. The first threshold voltage Vth1 is set to a voltage value that is higher than “−VF11+VF12” and lower than “Von+VF12.” The second threshold voltage Vth2 is set to a voltage value that is higher than “Von+VF12” and lower than “VB.” On the other hand, the comparator 22 outputs a high-level detection signal Vd that indicates that the transistor 13 is electrified when it detects that the input voltage Vin is higher than the first threshold voltage Vth1 and lower than the second threshold voltage Vth2. It should be noted that, in this case, when the transistor 13 is not electrified, the detection signal Vd is not used for the determination of whether to permit the transistor 13 to be turned on by the determination part 31 because the transistor 13 cannot be turned on even if a command signal Vg that commands turn-on of the transistor 13 is input.

As described above, because the protection diode 12 is provided on the common semiconductor substrate 10 on which the flyback diode 11 is provided, the variation in the voltage value of the input voltage Vin decreases. In addition, because the flyback diode 11 and the protection diode 12 are diodes of the same kind as described above, the variation in the voltage value of the input voltage Vin decreases. In addition, because the protection diode 12 is located at the central part 34 of the semiconductor substrate 10, the variation in the voltage value of the input voltage Vin decreases. Thus, according to this embodiment, the accuracy of the detection of the electrification direction of the reverse conducting transistor 14 or the accuracy of the detection of whether the transistor 13 is electrified can be improved.

What is claimed is:

1. A drive unit comprising:
a reverse conducting transistor including a transistor and a first diode being connected in inverse-parallel to the transistor, the transistor and the first diode being provided on a first semiconductor substrate;
a second diode including a cathode being connected to a collector of the transistor, the second diode being provided on the first semiconductor substrate; and
a detection portion configured to detect a voltage between the collector and an emitter of the transistor via an anode of the second diode.

2. The drive unit according to claim 1, wherein
the detection portion detects whether the first diode is electrified by detecting the voltage via the anode of the second diode.

3. The drive unit according to claim 1, wherein
the detection portion detects an electrification direction of the reverse conducting transistor by detecting the voltage via the anode of the second diode.

4. The drive unit according to claim 1, wherein
the detection portion detects whether the transistor is electrified by detecting the voltage via the anode of the second diode.

5. The drive unit according to claim 1, wherein
the detection portion is provided on a second semiconductor substrate being different from the first semiconductor substrate.

6. The drive unit according to claim 1, wherein
the first diode and the second diode are diodes of a same kind.

7. The drive unit according to claim 1, wherein
the second diode is located at a central part of the first semiconductor substrate.

8. The drive unit according to claim 1, wherein
the reverse conducting transistor is a reverse conducting insulated gate bipolar transistor.
